(19) United States
(12) Patent Application Publication
(10) Pub. No.: US 2005/0239295 A1
(43) Pub. Date: Oct. 27, 2005

(54) Chemical treatment of material surfaces

(76) Inventors: Pei-l Wang, Troy, NY (US); Toh-Ming Lu, Loudonville, NY (US); Shyam P. Murarka, Clifton Park, NY (US); Ramkrishna Ghoshal, Clifton Park, NY (US)

Correspondence Address: HESLIN ROTHENBERG FARLEY & MESITI PC, 5 COLUMBIA CIRCLE, ALBANY, NY, 12203, US

(21) Appl. No.: 10/832,629

(22) Filed: Apr. 27, 2004

(51) Int. Cl. H05K 3/36

(52) U.S. Cl. 438/780

(57) ABSTRACT

A method for treating the surfaces of materials to improve wettability and adhesion of subsequently deposited polymer layers is disclosed. Suitable materials for practice of the method include polymeric materials and silicon-containing materials is disclosed. The method involves contacting at least a portion of the surface of the material with an aqueous solution of sulfuric acid or phosphoric acid, followed by rinsing with water. After the acid treatment, the contact angle of the surface decreases, and subsequently deposited polymer coatings easily wet the material's surface and exhibit enhanced adhesion. The method may be used to fabricate useful structures, such as semiconductor structures, optical waveguide structures, and coated articles.

### CROSS-REFERENCE TO RELATED APPLICATIONS

This Application is related to the following U.S. Patent Applications: U.S. Patent Application entitled “SILOXANE EPOXY POLYMERS FOR LOW-κ DIELECTRIC APPLICATIONS” being filed concurrently herewith under Atty Dkt. No. 0665.020; and U.S. Patent Application entitled “SILOXANE EPOXY POLYMERS AS METAL DIFFUSION BARRIERS TO REDUCE ELECTROMIGRATION” being filed concurrently herewith under Atty Dkt. No. 0665.021.

Each of these Applications is hereby incorporated by reference herein in its entirety.

### FIELD OF THE INVENTION

The present invention relates to treating the surface of a material with a mineral acid, and more particularly to using the acid to improve the wettability and adhesive properties of the material surface.

### BACKGROUND OF THE INVENTION

Throughout industry, there are many examples of organic polymers being formed adjacent a polymeric material. For instance, in the fabrication of integrated circuits, multiple polymer films are often deposited to obtain low-k dielectric layers of various thicknesses. In addition, in the fabrication of optoelectronic waveguides, polymer films having different refractive indices are often positioned adjacent one another. Another example includes high performance metal coatings, where a polymer top coat is often applied to a cured polymer primer layer.

However, polymer adhesion problems are wide-spread throughout industry, largely because many cured polymers in the solid-state have chemically inert and nonporous surfaces with low surface tensions. The surfaces of these cured polymer materials are hydrophobic and not naturally wettable. Thus, subsequently deposited polymer solutions adhere poorly to the surface of the adjacent cured polymer.

As described in “TSG-Basics of Surface Wetting & Pretreatment Methods” published on the internet by The Sabreen Group and found at http://www.sabreen.com/surface_wetting_pretreatment, acceptable bonding adhesion is achieved when the surface energy of a solid substrate (measured in dynes/cm) is approximately 10 dynes/cm greater than the surface tension of the liquid. In this situation, the liquid is said to “wet out” or adhere to the surface. Surface tension, which is a measurement of surface energy, is the property, due to molecular forces, by which all liquids through contraction of the surface tend to bring the contained volume into a shape having the least surface area. The higher the surface energy of the solid substrate relative to the surface tension of a liquid, the better its “wettability”, and the smaller the contact angle. Good surface wettability exists, for example, when the substrate has a high surface energy and a contact angle <60°.

To overcome problems of adhesion, surface pretreatments are often employed to increase surface energy and improve the wetting and adhesive properties of polymer materials. Exemplary pretreatment processes currently being used in industry include RF cold gas plasma, electrical (corona discharge), and flame plasma. Each method is characterized by its ability to generate a “gas plasma”, which is an extremely reactive gas consisting of free electrons, positive ions, and other chemical species. The gas plasma impacts the surface with enough energy to break molecular bonds on the surface of the polymer surface, thereby creating very reactive free radicals. These free radicals can cross link, or in the presence of oxygen, react rapidly to form various chemical functional groups on the substrate surface. Polar finctional groups, which can form and enhance bondability, include carbonyl (C═O), carboxyl (HOOC), hydroperoxide (HOO—), and hydroxyl (HO—) groups. Nitrogen included in the gas plasma also functionalizes the surface to promote interaction of subsequently deposited materials on the surface. Even small amounts of reactive functional groups incorporated into polymers can be highly beneficial to improving surface characteristics and wettability.

However, gas plasma pretreatments are expensive to operate on a large-scale commercial level. In addition, special instrumentation and equipment are required. Furthermore, in the case of low-k dielectric polymers, there is a concern that the plasma processing from plasma pretreatments may damage the polymer's dielectric surface resulting in an increase in dielectric constant and an increase in leakage current. For these reasons, it would be desirable if a surface pretreatment of polymers could be developed that leaves the surface undamaged, as well as one that employs simple reagents without the need for expensive reagents or equipment.

Furthermore, in the microelectronics industry, organic polymer solutions are commonly deposited onto silicon wafer substrates and insulators, such as silicon dioxide. Similar wetting problems to those described above in connection with polymers also exist on the surface of silicon-containing materials. To overcome these problems, an adhesion promoter is typically applied to the surface of the silicon-containing material prior to deposition of a polymer solution. Examples of such adhesion promoters include hexamethyldisilazane (HMDS) and divinyltetramethyldisilazane (DVTMDS). However, such adhesion agents are costly. Therefore, it would also be advantageous if a method for improving the adhesive properties of the surfaces of silicon-containing materials could be developed to eliminate the need for expensive adhesion promoters.

### SUMMARY OF THE INVENTION

The present invention meets the aforementioned needs and unexpectedly provides a simple, inexpensive, and practical method for promoting the wettability of polymer surfaces, as well as that of silicon-containing materials. The novel process dramatically decreases the contact angle of the surface, as well as making the surface hydrophilic. Subsequent polymer coatings easily wet the underlying surface and exhibit enhanced adhesion. The method is advantageous over existing gas plasma surface pretreatments, in part, because of its ease of operation, its use of inexpensive reagents, and its cost-effectiveness.

The present invention relates to a method of chemically treating polymeric surfaces and surfaces of silicon-containing materials to improve wetting and adhesion of subsequently deposited polymer solutions. Therefore, in one aspect, the invention relates to a method of treating at least a portion of the surface of a material by contacting at least a portion of the surface of the material with an aqueous solution of sulfuric acid or phosphoric acid. The material is selected from the group of polymeric materials and silicon-containing materials.

In another aspect, the present invention relates to a method of fabricating a useful structure. Exemplary useful structures include, but are not limited to, semiconductor structures, optical waveguide structures, and coated articles. The first step comprises depositing a first prepolymer layer onto a substrate surface, wherein the first prepolymer is in liquid form. After deposition, the first prepolymer layer is cured to form a first cured polymeric material layer having an exposed surface opposite the substrate surface, and the first cured polymeric material layer is in solid form. Next, the exposed surface of the first cured polymer layer is contacted with an aqueous solution of sulfuric acid or phosphoric acid, followed by rinsing the aqueous solution of sulfuric acid or phosphoric acid from the exposed surface with water to form a treated surface of the first cured polymer layer. A second prepolymer layer in liquid form is then deposited onto the treated surface of the first cured polymeric material layer, and the deposited second prepolymer layer is cured to form a second cured polymeric material layer in solid form.

In yet another aspect, the present invention relates to a method of fabricating a semiconductor structure. The first step comprises depositing a capping layer onto a metallization layer comprising a first polymeric dielectric layer having a via formed therein, wherein the via is filled with a conductive metal, and wherein the capping layer has an exposed surface opposite the first polymeric dielectric layer and the conductive metal. The second step comprises contacting the exposed surface of the capping layer with an aqueous solution of sulfuric acid or phosphoric acid, followed by rinsing the aqueous solution of sulfuric acid or phosphoric acid from the exposed surface with water to form a treated surface of the capping layer. Next, a prepolymer dielectric layer is deposited in liquid form onto the treated surface of the capping layer, followed by curing the second prepolymer dielectric layer to form a second polymeric dielectric layer.

### BRIEF DESCRIPTION OF THE DRAWINGS

FIG. 1 is an atomic force microscopy (AFM) image illustrating the surface roughness of the surface of a cured polymer layer.

FIG. 2 is an x-ray photoelectron spectroscopy (XPS) spectrum of a cured first polymer layer, as deposited.

FIG. 3 is an x-ray photoelectron spectroscopy (XPS) spectrum of the cured first polymer layer of FIG. 2 after treatment with sulfuric acid in accordance with the present invention.

FIG. 4 is an optical image of the surface of a second polymer layer coated onto a cured first polymer layer, which shows the wettability of the second polymer when the surface of the first polymer layer is untreated, as well as the wettability of the second polymer when the surface of the first polymer layer is treated with acid, in accordance with the present invention.

FIG. 5 is a cross-sectional view of a portion of a semiconductor structure having a silicon-containing dielectric capping layer on which the method of the present invention is performed; and

FIG. 6 is a cross-sectional view of a portion of a semiconductor structure having a siloxane epoxy polymeric layer dielectric capping layer on which the method of the present invention is performed.

### DETAILED DESCRIPTION OF THE INVENTION

The method of the present invention improves the surface properties of polymeric films and silicon-containing materials for subsequent deposition of polymer solutions thereon without the need for expensive equipment or adhesion promoters. Unexpectedly, by treating the surface with a strong mineral acid, wetting of the treated surface is enhanced, as well as adhesion.

According to the method, the portion of the surface of the material to be treated is contacted with a strong mineral acid solution, such as a strong aqueous solution of phosphoric acid or sulfuric acid. Suitable concentrations of the acid in water range from about 30 wt. % to about 85 wt. %, but about 50 wt. % is typical.

Contact of the material surface with the acid solution may be effected by conventional techniques, such as dipping, immersion, spraying, or direct application, such as by brushing, for example. Dipping or immersion of the material surface is usually preferred. Generally, contact between the acid and the material surface for a time ranging from about 15 to about 60 seconds, but typically about 30 seconds, is sufficient to alter the surface of the substrate and improve adhesion and wetting. The reaction between the acid and the material tends to be self-limiting when the acid solution is at room temperature, thereby providing more flexibility to the pretreatment process. The temperature of the acid solution is typically room temperature, i.e. about 25° C. However, an increase in temperature of the acid solution will often reduce the contact angle of the surface of the material even further, especially when phosphoric acid is employed as the acid. Generally, an acid solution temperature ranging from about 20° C. to about 75° C. is suitable.

After the surface of the material has been contacted and treated with the mineral acid, then water, typically deionized water, may be used to rinse the acid from the material's surface. Typically, this is done using conventional techniques, such as those listed above. Again, dipping of the material is frequently employed. After rinsing, the surface is then typically dried to remove any free water. Following treatment with the present method, a second layer, comprising an uncured prepolymer in the liquid state, may then be deposited atop the treated surface of the material without dewetting.

The mineral acid treatment method described herein may be performed on organic/inorganic polymeric materials or silicon-containing materials. As used herein, the term “polymeric material” includes polymers and formulations comprising polymers, polymerization initiators, and other ingredients. In addition, as will be obvious to those of skill, the polymeric materials are solid-state materials that have typically been prepared by curing a corresponding prepolymer in the liquid state prior to performing the surface acid treatment of the present invention. Curing, either thermally or by actinic radiation, aids in cross-linking, as well as in polymerizing the prepolymer. Furthermore, curing changes the physical properties of the prepolymer by chemical reaction, and typically polymerization occurs to >50%. A “prepolymer” contains the same structural units as the polymeric material, but the prepolymer has not yet been cured to form the solid state polymeric material. Although liquid, the prepolymer may often be very viscous. As used herein, “prepolymer” also includes formulations comprising the prepolymers, polymerization initiators, solvents, and other ingredients.

The polymeric materials include polymers conventionally used as dielectrics in the semiconductor industry, polymer formulations used as primer coatings in the metal coating industry, and polymers used to make optical waveguides. However, as one of skill would know, polymeric materials used in many other applications may also be suitable for treatment by the present method.

Exemplary dielectric polymeric materials include, but are not limited to, polyimides, parylene (poly-p-xylylene), polynaphthalene, benzocyclobutane (BCB), silicon-containing organic polymers, such as methyl silsesquioxane (MSQ), and hydrogen silsesquioxane (HSQ), and aromatic hydrocarbon polymers, such as SiLK™, which contains phenylene and carbonyl groups in the main chain, Nautilus™, and FLARE™, which is a poly(arylene) ether. SiLK™ and Nautilus™ are available from Dow Chemical Company. FLARE™ is manufactured by Allied Signal. Other polymeric materials include siloxane epoxy polymers and formulations containing them, some of which may be used as low k dielectric materials in the semiconductor industry, or as materials having varying refractive indices for use in waveguide fabrication, and others of which may be included in formulations useful in metal coating applications. However, the method of the present invention is not limited to the aforementioned materials.

Exemplary siloxane epoxy polymers suitable for operation of the present method include those commercially available from Polyset Company, Inc. of Mechanicville, N.Y. as PC 2000, PC 2003, PC 2000 HV, each of which has the following structure (I) 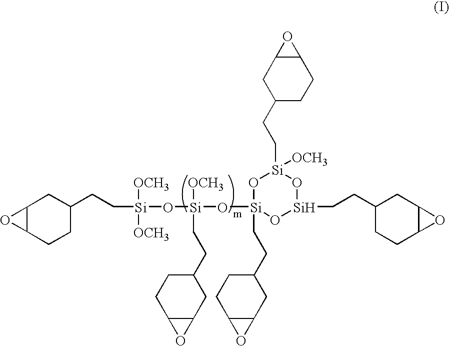
wherein m is an integer from 5 to 50. The molecular weights of these polymers range from about 1000 to about 10,000 g/mole.

Other suitable polymers include random and block copolymers having the following general following formula (II): 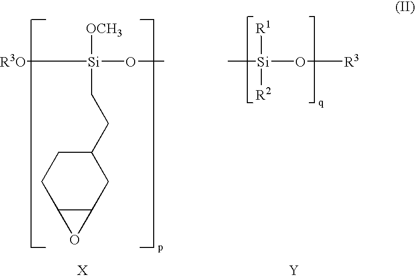
wherein the X monomer units and Y monomer units may be randomly distributed in the polymer chain. Alternatively, like repeating units, X and Y, respectively, may occur together in a block structure. Preferably, R¹ and R² are each independently methyl, methoxy, ethyl, ethoxy, propyl, butyl, pentyl, octyl, and phenyl, and R³ is methyl or ethyl. In addition, p is an integer ranging from 2 to 50; and q ranges from 0 to 50. Most preferably, R³ in the terminal residues at the end of the polymer chain is methyl, resulting in a polymer having structure (IIA), which will be the embodiment discussed herein. However, the invention may also be applied to polymers wherein R³ is ethyl.

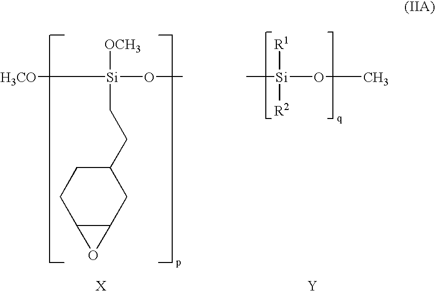

Exemplary polymers having structure (IIA) include Polyset's PC 2010, PC 2021, and PC 2026. In PC 2010, R¹ and R² in structure (IIA) are both phenyl groups, and the ratio of p to q ranges from about 8:1 to about 1:1, but is usually about 4:1 to about 2:1. The molecular weight of PC 2010 ranges from about 5000 to about 7500 g/mole. In PC 2021, R¹ and R² are both methyl groups, as shown in structure (IIB), and the ratio of p to q ranges from about 8:1 to about 1:1, but is usually about 4:1 to about 2:1. The molecular weight of PC 2021 ranges from about 2000 to about 7500 g/mole. In PC 2026, R¹ is trifluoropropyl, and R² is a methyl group. The ratio of p:q is typically about 3:1. The molecular weight of PC 2026 ranges from about 5000 to about 7500 g/mole.

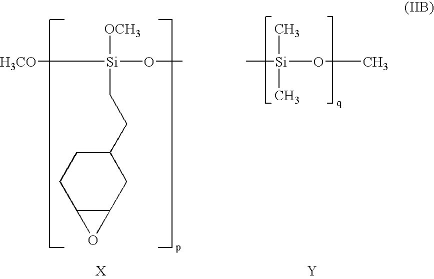

Siloxane epoxy polymers of structure (II) containing monomer units X and Y may be synthesized by base-catalyzed hydrolysis and subsequent condensation of alkoxy silane monomers, using 0.5 to 2.5 equivalents of water in the presence of an ion exchange resin, such as Amberlyst A-26, Amberlite IRA-400 and Amberlite IRA-904 from Rohm & Haas, in the presence of an alcohol solvent, followed by separation of the siloxane oligomer from the water/solvent mixture. The procedure for the polymerization is described fully in U.S. Pat. Nos. 6,069,259 and 6,391,999 and copending, commonly assigned U.S. application Ser. No. 10/269,246 filed Oct. 11, 2002.

In structure (II), the alkoxy silane monomer from which the X units are derived may be 2-(3,4-epoxycyclohexylethyl)trimethoxy silane, which is commercially available as A-186 from Witco Corporation. Exemplary monomers used to provide the Y units include tetraethoxysilane (ethylorthosilicate), tetramethoxysilane (methylorthosilicate), tetraisopropoxysilane, methyltrimethoxysilane, ethyltriethoxysilane, hexyltriethoxysilane, cyclohexyltrimethoxysilane, 1,1,1-trifluoroethyltriethoxysilane, phenyltriethoxysilane, phenylmethyldiethoxysilane, phenylmethyldimethoxysilane, diphenyldimethoxysilane (used in PC 2010), 2-phenylethyltrimethoxysilane, benzyltriethoxysilane, vinyltrimethoxysilane, dimethyldimethoxysilane (used in PC 2021), methylpropyldimethoxysilane, dipropyldimethoxysilane, dibutyldimethoxysilane, methylpentyldimethoxysilane, dipentyldimethoxysilane, dioctyldimethoxysilane, dimethyldiethoxysilane, trimethylmethoxysilane, diethyldimethoxysilane, allyltrimethoxysilane, divinyldimethoxysilane, methyvinyldimethoxysilane, bis(triethoxysilyl)methane, bis(triethoxysilyl)ethane, butenyltrimethoxysilane, trifluoropropylmethyldimethoxysilane (used in PC 2026), 3-bromopropyltrimethoxysilane, 2-chloroethylmethyldimethoxysilane, 1,1,2,2-tetramethoxy-1,3-dimethyldisiloxane, phenyltrimethoxysilane. Also, useful in these mixtures are trimethoxysilyl-terminated polydimethylsiloxanes as well as the corresponding hydroxyl-terminated polydimethylsiloxanes. The foregoing monomers are either commercially available or readily synthesized by reactions well known in the art.

One embodiment of a polymer having structure (IIA), which is useful as a low k dielectric material in semiconductor structures, is synthesized from 2-(3,4-epoxycyclohexylethyl)trimethoxy silane (A-186) (to form the X units), and dimethyldimethoxysilane (to form the Y units). In the resulting polymer, depicted in structure (IIB), R¹ and R² are both methyl groups, and the ratio of p to q ranges from about 8:1 to about 1:1, but is usually about 4:1 to about 2:1.

Other polymeric materials suitable for the method of the present invention include those useful as coatings for metal, plastics, glass, or wood. Prior to curing, the coating formulations comprise a cycloaliphatic epoxy siloxane monomer having structure (III) 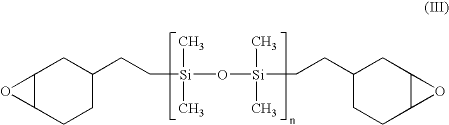
wherein n is an integer ranging from 1-3. The monomer having structure (III) may optionally be combined with the epoxy siloxane oligomer having structure (I) above. When n is 1, structure (III) has the chemical name 1,1,3,3-tetramethyl-1,3-bis[2-(7-oxabicyclo[4.1.0]hept-3-yl)ethyl] disiloxane and is commercially available from Polyset Company, Inc. as PC1000. Also included in the coating formulations is a non-silicon-containing epoxy, e.g., epoxidized vegetable oils, epoxidized vegetable oil esters, diglycidyl ethers of bisphenol A epoxy resins, oxetanes or 3,4-epoxycyclohexyl 3′,4′-epoxycyclohexane carboxylate, and a polymerization initiator, such as a diaryliodonium salt catalyst in solution. Flexibilizers, fillers, pigments, diluents, tougheners, flow control agents, antifoaming agents; and an adhesion promoter are optionally included in the formulations. Upon curing such polymeric materials are useful as coatings, as fully disclosed in copending, commonly assigned U.S. application Ser. No. 10/636,101 filed Aug. 7, 2003.

As previously mentioned, the solid state siloxane epoxy polymeric materials discussed herein are typically prepared by curing the corresponding prepolymers/formulations by art-recognized techniques, such as thermally or by using actinic radiation, such as U.V., visable, or electron beam. A polymerization initiator or catalyst may also be added to the prepolymer. Such polymerization initiators include, for example, free radical initiators and cationic initiators. For polymerization of acrylate and methacrylate functional polymers, peroxide and azo free radical initiators may be used to cure the polymers thermally or by photoinitiation. A plethora of free radical photoinitiators may be used including, for example, benzoin, benzoin alkyl ethers, 1,1-diethoxyacetophenone, 1-benzoylcyclohexanol and many others. Epoxy, 1-propenyl ether, 1-butenyl ether and vinyl ether functional oligomers can be thermally cured or photopolymerized using UV or visible irradiation, i.e. actinic, or electron beam irradiation in the presence of a cationic initiator such as a diazonium, sulfonium, phosphonium, or iodonium salt, but more preferably a diaryliodonium, dialkylphenacylsulfonium, triarylsulfonium, or ferrocenium salt photoinitiator. Such photoinitiators are discussed in detail in the aforementioned co-pending commonly assigned U.S. application Ser. No. 10/636,101 filed Aug. 7, 2003; copending, commonly assigned U.S. application Ser. No. 10/269,246 filed Oct. 11, 2002; copending commonly assigned U.S. application Ser. No. 09/489,405 filed Jan. 21, 2000, U.S. Pat. No. 6,632,960, and U.S. Pat. No. 6,069,259.

Depending on the thickness of the film, thermal curing is generally performed by heating the prepolymer to a temperature ranging from about 155° C. to about 360° C., but preferably about 165° C., for a period of time ranging from about 0.5 to about 2 hours. In formulations curable by U.V. light, the films may be flood exposed by U.V. light (>300 mJ/cm² @250-380 nm). Curing by E-beam radiation is often done at a dosage ranging from about 3 to about 12 Mrad. Often a thermal bake will be used in combination with a cure by U.V. or E-beam radiation. The particular prepolymer or formulation containing the prepolymer will determine which curing method will be used, as one of skill would know. Following curing, a thermal anneal will often be employed under nitrogen at temperatures ranging from about 200° C. to about 300° C., but preferably about 250° C. for a period of time ranging from about 1 to about 3 hours, but preferably about 2 hours.

After any of the above prepolymers has been cured to form the corresponding solid-state polymeric material, each resulting solid polymer film is very hydrophobic on its surface. This is advantageous because moisture uptake is prevented. However, as mentioned above, it is difficult to deposit, typically by spin coating, a second prepolymer layer in sequence because of the high contact angle of the first film surface. Instead, dewetting occurs during the second spin coating process. However, the present method of contacting the surface of the first polymeric material layer with phosphoric acid or sulfuric acid unexpectedly and dramatically decreases the contact angle, and a second prepolymer layer can easily be deposited thereon, thereby wetting the underlying surface.

Silicon-containing materials suitable for treatment with the mineral acids described herein include but are not limited to, silicon, such as in silicon wafers, silicon oxide, silicon dioxide, silicon oxide/silicon, silicon nitride, silica on silicon, boron-doped silicon (n-type), phosphorous-doped silicon (p-type), arsenic-doped silicon (p-type), polysilicon, etc. These materials are also very hydrophobic on their surfaces. Typically, an adhesion promoter, such as HMDS or DVTMDS, is applied to the surface before depositing a prepolymer solution onto it. However, the process of contacting the silicon surface with an aqueous phosphoric acid or sulfuric acid solution eliminates the need for the adhesion promoter, and the prepolymer can be deposited, typically by spin-casting, directly onto it without dewetting.

The following examples are given by way of illustration and are not intended to be limitative of the present invention. The reagents and other materials used in the examples are readily available materials, which can be conveniently prepared in accordance with conventional preparatory procedures or obtained from commercial sources. The equilibrium contact angles were conventionally measured by use of the sessile drop technique according to the method of Good.

### EXAMPLE 1

An N-type, 4-inch silicon wafer having a resistivity of 0-0.02 ohm-cm was used as the substrate. After standard RCA cleaning an adhesion promoter (HMDS) was spin-coated onto the wafer at 3000 rpm for 40 sec. The wafer was then annealed in air at 100° C. for 10 min. A siloxane epoxy prepolymer solution containing structure (IIB), wherein the ratio of p to q was about 2:1, was spin-coated onto the wafer at 3000 rpm for 100 sec to a thickness of 0.5 micron to form a first layer. The first polymeric film/wafer was baked under vacuum of 10⁻³ torr for 1 hour at 100° C. The film was then cured at 165° C. for 2 hours, followed by a thermal anneal at 250° C. under nitrogen gas flow for 1 hour to cross-link the polymer. The contact angle of the cured first polymer layer was measured to be 70°.

### COMPARATIVE EXAMPLE 1A

The procedure of Example 1 was followed. The cured first layer polymer film was then dipped in diluted sulfuric acid (50% by weight) for 30 seconds at room temperature, and then dipped in deionized water for 30 seconds at room temperature. A dramatic change in the contact angle occurred. It reduced from 70° to 35°-40°.

### COMPARATIVE EXAMPLE 1B

The procedure of Example 1 was followed. The cured first layer polymer film was then dipped in diluted phosphoric acid (85% by weight) for 30 seconds at room temperature, and then dipped in deionized water for 30 seconds at room temperature. The contact angle reduced from 70° to 55°.

### COMPARATIVE EXAMPLE 1C

The procedure of Example 1 was followed. The cured first layer polymer film was then dipped in diluted phosphoric acid (85% by weight) at 50° C. for 30 seconds and then dipped in deionized water for 30 seconds at room temperature. The contact angle reduced from 70° to 50°.

### COMPARATIVE EXAMPLE 1D

The procedure of Example 1 was followed. The cured first layer polymer film was then dipped in diluted phosphoric acid (85% by weight) at 80° C. for 30 seconds, and then dipped in deionized water for 30 seconds at room temperature. The contact angle reduced from 70° to 40°.

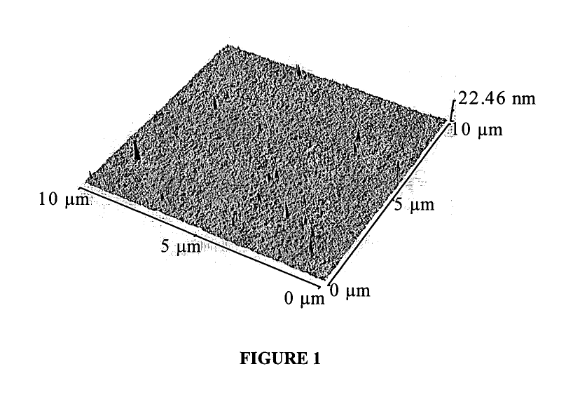

FIG. 1 is an atomic force microscopy (AFM) image of the surface of the cured first polymer layer of Example 1. The surface roughness measurement was 0.75 nm. The process of the present invention was then performed on the surface, as described in Comparative Example 1A, and the surface roughness was measured again. There was no observable change in the surface roughness of the film after the surface was treated with sulfuric acid.

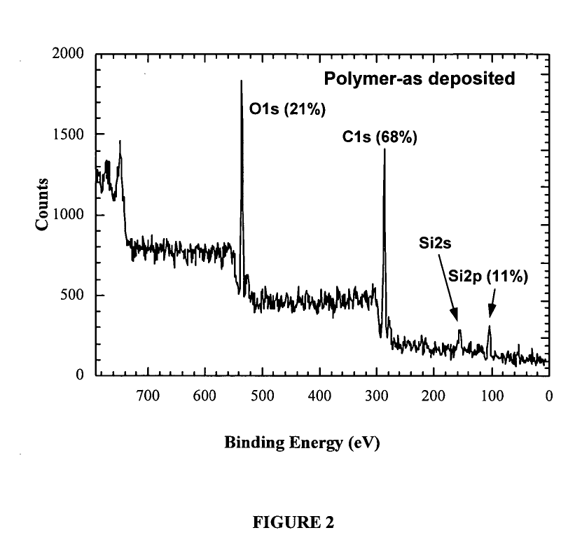

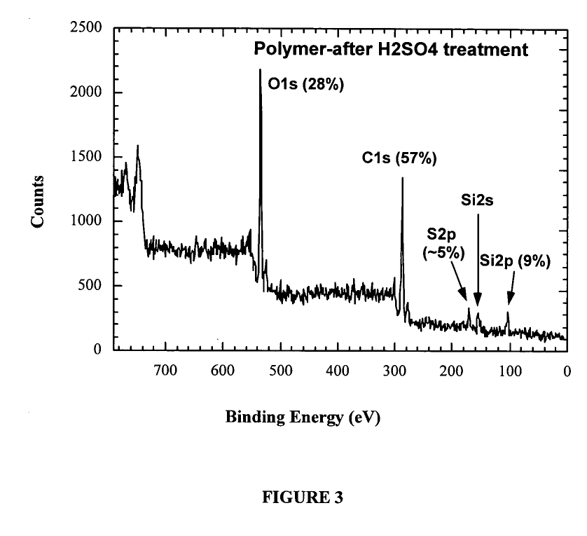

FIGS. 2 and 3, respectively, show the x-ray photoelectron spectroscopy (XPS) spectra of the cured first polymer layer from Example 1 (as deposited) and Example 1A (treated with sulfuric acid). As indicated by the spectra, the sum of atomic percentages of sulfur and oxygen increases ≈10% after the surface treatment of the present method. Correspondingly, the percentage of carbon decreases ≈10%. This XPS result indicates that the surface layer of the methyl group on the polymer has been substituted by oxygen and sulfur. No observable change of film thickness and surface roughness after treatment with sulfuric acid suggests that the substitution of chemical bonding on the film surface is about an atomic layer level and is very uniform.

### EXAMPLE 2

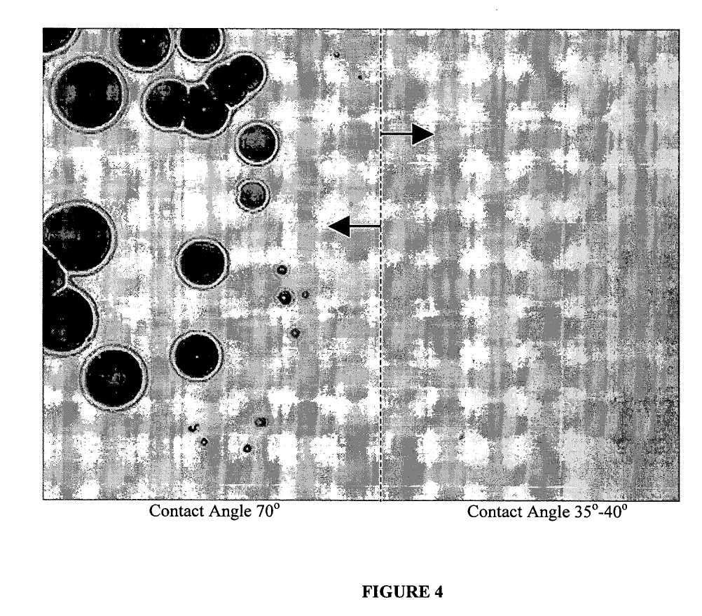

The procedure of Example 1 was followed, and a second prepolymer layer was spun onto the surface of the cured first polymer layer (3000 rpm for 100 sec to a thickness of 0.5 micron). The prepolymer deposited as the second layer was the same as that deposited as the first layer polymer described in Example 1. However, the first polymer layer surface dewetted during the spin on process of the second prepolymer layer, as shown in the left side of FIG. 4, described below.

### COMPARATIVE EXAMPLE 2

The procedure of Comparative Example 1A was followed, and a second prepolymer layer was spun (3000 rpm for 100 sec to a thickness of 0.5 micron) onto the surface of the sulfuric acid treated first polymeric layer, completely wetting the surface (see the right side of FIG. 4). The prepolymer deposited as the second layer was the same as that deposited as the first layer polymer described in Example 1.

FIG. 4 is an optical image of the surface of a second prepolymer layer coated onto the surface of a cured first polymer layer. The left side of FIG. 4 is the surface image for Example 2 and shows dewetting when the surface of the first polymer layer is untreated. The right side of FIG. 4 is the surface image for Comparative Example 2 and shows that wetting occurs when the surface of the first polymer layer is treated using the process of the present invention.

Also included in the present invention is a method of fabricating useful structures, such as semiconductor structures, optical waveguides, or coated articles comprising glass, plastic, or metal, to name a few. Briefly, in one embodiment, a first prepolymer layer in liquid form is deposited onto a substrate surface, which is preferably planar, followed by curing, as described above to form a first cured polymeric material layer in solid form having an exposed surface opposite the substrate surface. The exposed surface of the cured polymer is then contacted with an aqueous solution of sulfuric acid or phosphoric acid; as previously described, followed by removal of the acid by rinsing with water, preferably deionized water. This forms a treated surface on the first cured polymeric material layer. A second prepolymer layer is then deposited onto the treated surface of the first polymer, followed by curing.

When the useful structure is a semiconductor structure containing for example, adjacent interlayer dielectric materials, the substrate is typically one of the aforementioned silicon containing materials. Thus, if desired, prior to depositing the prepolymer layer onto it, the surface of the silicon substrate may be treated with a solution of sulfuric acid or phosphoric acid, in accordance with the present invention, followed by rinsing with water. The first prepolymer layer is typically deposited onto the silicon substrate to a thickness ranging from about 0.02 to about 2 μm, but is typically from about 0.1 to about 0.7 μm. Deposition of the first prepolymer onto the substrate may be done by any known method, such as by spin casting (also referred to herein as “spin coating”), dip coating, roller coating, doctor blading, evaporating, chemical vapor deposition (CVD), or plasma-enhanced chemical vapor deposition (PECVD), for example. Typically, spin casting is used. The first prepolymer layer will often be a low k-dielectric material, such as a polyimide, parylene (poly-p-xylylene), polynaphthalene, BCB (benzocyclobutane), a porous or non-porous silicon-containing organic polymer, e.g. HSQ (hydrogen silsesquioxane), MSQ (methyl silsesquioxane), an aromatic hydrocarbon polymer, e.g., SiLK™, Nautilus™, or FLARE™, or a siloxane epoxy polymer having structure (I) or (IIA). However, the invention is not limited to these polymers. Curing is often effected by heating the prepolymer to a temperature ranging from about 155° C. to about 360° C., but preferably about 165° C., for a period of time ranging from about 0.5 to about 2 hours. Alternatively, when the prepolymer has structure (IIA), a U.V. cure may be performed, as previously described. In addition, a thermal anneal may be performed if desired at a temperature ranging from about 200° C. to about 300° C., but preferably about 250° C. for a period of time ranging from about 1 to about 3 hours, but preferably about 2 hours. After performing the acid surface treatment on the cured first polymeric layer, a second prepolymer, similar or the same as the first prepolymer is deposited atop the cured first polymeric material layer using any of the techniques previously described, followed by curing. Again, the second prepolymer is typically a low-k dielectric material.

In another embodiment of fabricating a semiconductor structure, such as a metal interconnect structure, a dielectric capping or barrier layer may initially be deposited onto an underlying conductive metallization layer comprising a first polymeric dielectric layer having a via or contact hole formed therein. The first polymeric dielectric layer is typically one of the low-k dielectric polymers previously mentioned herein. The via is filled with a conductive metal, such as copper, a copper alloy, aluminum, or tungsten, for example, but preferably copper. In this embodiment, the via, as well as any trenches, is typically formed in the first polymeric dielectric layer using conventional damascene processing steps, such as etching, followed by deposition of the conductive metal into the via and planarization, typically by chemical mechanical planarization (CMP). The capping/barrier layer is then deposited, typically by spin-coating or chemical vapor deposition, to a thickness ranging from about 0.02 μm to about 10 μm, but more typically from about 0.02 μm to about 0.05 μm. Examples of materials useful as capping layers include silicon-containing materials, such as SiN, SiC, SiCH, and SiCN. The capping layer 60 may also be a siloxane epoxy polymer having structure (I) or (II), as fully described in the aforementioned related U.S. application entitled “SILOXANE EPOXY POLYMERS AS METAL DIFFUSION BARRIERS TO REDUCE ELECTROMIGRATION” being filed concurrently herewith under Atty Dkt. No. 0665.021. Next, the exposed surface of the capping layer is contacted with an aqueous solution of sulfuric acid or phosphoric acid, as previously described, followed by rinsing with water and drying to form a treated surface. A second polymeric dielectric layer is deposited by CVD or in liquid form, i.e., prepolymer, by spin-coating onto the treated surface of the capping layer, followed by curing. Like the first polymeric dielectric, the prepolymer from which the second polymeric dielectric layer is formed is typically one of the previously mentioned low-k dielectrics, such as siloxane epoxy polymers, polyimides, parylene (poly-p-xylylene), polynaphthalene, benzocyclobutane (BCB), hydrogen silsesquioxane (HSQ), methyl silsesquioxane (MSQ), SiLK™, Nautilus™, or FLARE™. In addition, the first and second polymeric dielectrics may be the same material or may be different.

### EXAMPLE 3

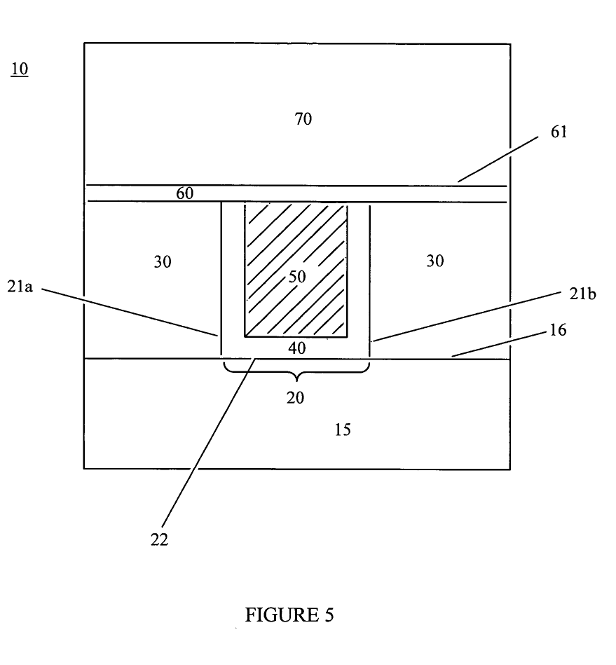

FIG. 5 is a cross-sectional view of a portion 10 of a semiconductor structure fabricated using conventional damascene processing, wherein trenches (lines) and vias (holes) are etched into interlayer dielectric 30. Initially, a low-k prepolymer, such as parylene, is deposited by chemical vapor deposition (CVD) (and cured) to a thickness typically of up to 0.7 μm onto top surface 16 of semiconductor substrate 15 made of polysilicon, for example, to form first polymeric low-k interlayer dielectric 30. Via 20 is etched into first polymeric low-k interlayer dielectric 30. Ta-based liner 40, made of tantalum, TaN, or TaSiN, is conformally deposited onto sidewalls 21a and 21b and bottom 22 of via 20 (and any trenches, not shown), followed by deposition of copper 50 and planarization. Silicon-containing dielectric cap 60 made of SiN, SiC, SiCH, or SiCN is then deposited by CVD onto the top surfaces of copper line 50, Ta-based barrier 40 and low-k polymeric dielectric 30 to a thickness usually ranging from about 0.03 μm to about 0.05 μm. Dielectric cap 60 acts as a diffusion barrier, as well as an etch stop layer. The exposed surface 61 of silicon-containing dielectric cap 60 is then contacted with an aqueous solution of sulfuric acid (50% by weight) or phosphoric acid (85% by weight) for 30 seconds at room temperature, followed by removal of the acid solution by rinsing with deionized water for 30 seconds at room temperature and drying. This treated surface of silicon containing dielectric cap 60 thus facilitates the wetting of second polymeric low k dielectric material layer 70 deposited by CVD onto dielectric cap 60 or deposited by spin-coating onto dielectric cap 60 as a prepolymer and cured. The first and second polymeric low k dielectric material layers 30 and 70 may be the same or different materials.

### EXAMPLE 4

The procedure of Example 3 is followed except that prior to depositing the low-k prepolymer onto silicon-containing semiconductor substrate 15, top surface 16 is contacted with an aqueous solution of sulfuric acid (50% by weight) or phosphoric acid (85% by weight) for 30 seconds at room temperature, followed by removal of the acid solution by rinsing with deionized water for 30 seconds at room temperature, and drying.

### EXAMPLE 5

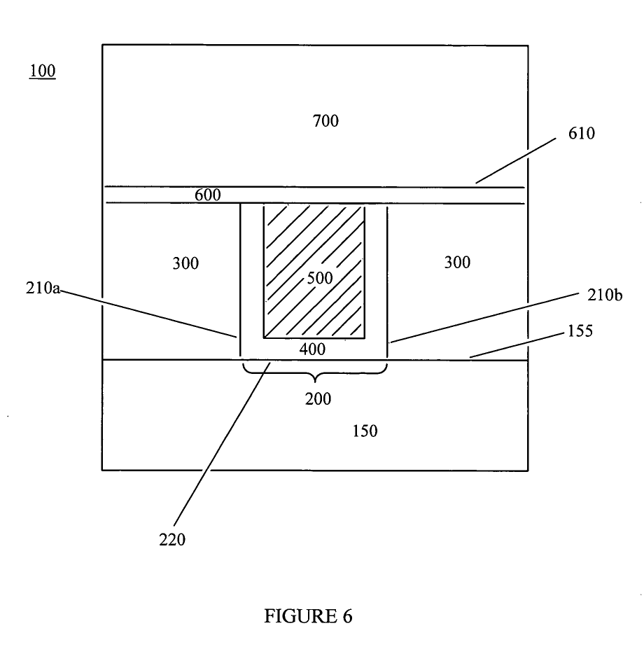

FIG. 6 is a cross-sectional view of a portion 100 of a semiconductor structure fabricated using conventional damascene processing, wherein trenches (lines) and vias (holes) are etched into low-k dielectric 30. Initially, a low-k prepolymer, such as parylene, for example is deposited by CVD and cured to a thickness typically of up to 0.7 μm onto top surface 160 of semiconductor substrate 15 made of polysilicon, for example, to form first polymeric low-k interlayer dielectric 300. Via 200 is etched into first polymeric low-k interlayer dielectric 300. Ta-based liner 400, made of tantalum, TaN, or TaSiN, is conformally deposited onto sidewalls 210a and 210b and bottom 220 of via 200 (and any trenches, not shown) followed by deposition of copper 500 and planarization. Siloxane epoxy prepolymer capping layer 600 having structure (IIB), wherein the ratio of p to q is about 2:1, is spin-coated onto the top surfaces of copper line 500, Ta-based barrier 400 and low-k dielectric 300 at 3000 rpm for 100 sec to a thickness usually ranging from about 0.03 μm to about 0.05 μm. The polymeric film 600 is baked under vacuum (10⁻³ torr) for 1 hour at 100° C., cured at 165° C. for 2 hours, and thermally annealed at 250° C. under nitrogen gas flow for 1 hour to form capping layer 600. Siloxane epoxy polymer capping layer 600 acts as a diffusion barrier, as well as an etch stop layer. The exposed surface 610 of the cured polymer 600 is then contacted with an aqueous solution of sulfuric acid (50% by weight) or phosphoric acid (85% by weight) for 30 seconds at room temperature, followed by removal of the acid solution by rinsing with deionized water for 30 seconds at room temperature and drying. This treated surface of the polymer 600 thus facilitates the wetting of second polymeric low k dielectric material layer 700 deposited onto capping layer 600 as a prepolymer and cured.

### EXAMPLE 6

The procedure of Example 5 is followed except that both first and second polymeric layers 300 and 700 comprise a prepolymer having structure (IIB), wherein the ratio of p to q is about 2:1, which is baked under vacuum (10⁻³ torr) for 1 hour at 100° C., cured at 165° C. for 2 hours, and thermally annealed at 250° C. under nitrogen gas flow for 1 hour.

When the useful product is an optical waveguide structure, the substrate may also be a silicon substrate. Thus, the acid treatment of the present method is then optionally performed on the silicon substrate. Other suitable substrates include glass, plastics, quartz, ceramics, or crystalline materials. The first prepolymer layer acts as a cladding for the waveguide. Suitable prepolymers for use as the cladding include siloxane epoxy polymers having structure (I) or (II). The cladding is generally deposited onto the substrate using any of the aforementioned methods to a thickness ranging from about 0.5 μm to about 10 μm, but more typically ranging from about 1 to about 5 μm. Curing may be effected thermally or by U.V. radiation, as previously described. When U.V. radiation is used, a thermal postbake may be may be performed after curing at a temperature ranging from about 130° C. to about 170° C. for a period of time ranging from about ½ to about 1 hour, but preferably performed at about 150° C. for about ½ hour. The acid treatment of the present invention is then performed on the cured cladding layer. The second prepolymer layer deposited onto the first cured polymeric material layer acts as the core of the waveguide and is frequently deposited to a thickness ranging from about 0.5 μm to about 10 μm. In one embodiment, the second prepolymer will also be a siloxane epoxy material having structure (I) or (II), but the cladding (first cured polymeric material layer) must have a refractive index lower than that of the core (second cured polymeric material layer). Thus, the two prepolymers cannot be the same.

In another embodiment, the useful product is a coated article, and the substrate i.e., article is glass, plastic, or metal, but typically metal. The first prepolymer layer is a composition comprising a cycloaliphatic epoxy siloxane monomer having structure (III) in combination with a non-silicon-containing epoxy, e.g., diglycidyl ethers of bisphenol A epoxy resins, epoxidized vegetable oils, epoxidized vegetable oil esters, or 3,4-epoxycyclohexyl 3′,4′-epoxycyclohexane carboxylate, and a polymerization initiator, such as a diaryliodonium salt catalyst in solution. Optionally included in the coating compositions is the epoxy siloxane oligomer having structure (I) or oxetanes. Other optional ingredients include one or more of the following: flexibilizers, fillers, pigments, diluents, tougheners, flow control agents, antifoaming agents, or adhesion promoters, as fully disclosed in previously mentioned copending, commonly assigned U.S. application Ser. No. 10/636,101 filed Aug. 7, 2003. The first prepolymer layer is deposited onto the article by conventional techniques known in the art, such as spray or roll coating. Next, the first prepolymer composition is cured by exposure to E-beam radiation ranging from about 3 to about 12 Mrad or by heating to a temperature ranging from about 150° C. to about 260° C. The acid treatment method of the present invention is then performed on the resulting first polymeric material layer. A second prepolymer layer comprising a composition similar to the first layer is then deposited on the cured first polymeric material layer.

Each of the patents, patent applications, and references mentioned herein is hereby incorporated by reference in its entirety.

The invention has been described in detail with particular reference to preferred embodiments thereof, but it will be understood by those skilled in the art that variations and modifications can be effected within the spirit and scope of the invention.

1. A method of treating at least a portion of the surface of a material comprising contacting said at least a portion of the surface of said material with an aqueous solution of sulfuric acid or phosphoric acid, wherein said material is selected from the group of polymeric materials and silicon-containing materials.

2. The method of claim 1, wherein the concentration of said sulfuric acid or phosphoric acid in water ranges from about 30 wt. % to about 85 wt. %.

3. The method of claim 1, wherein said contacting is made by dipping, immersion, spraying, or direct application.

4. The method of claim 1, wherein the temperature of said aqueous solution of sulfuric acid or phosphoric acid ranges from about 20° C. to about 75° C.

5. The method of claim 1, wherein said contacting occurs for a time ranging from about 15 seconds to about 60 seconds.

6. The method of claim 1, wherein said polymeric material is selected from the group of siloxane epoxy polymers, polyimides, parylene (poly-p-xylylene), polynaphthalene, benzocyclobutane (BCB), silicon-containing organic polymers, and aromatic hydrocarbon polymers.

7. The method of claim 1, wherein said polymeric material is selected from the group of siloxane epoxy polymers having structures (I) and (II): 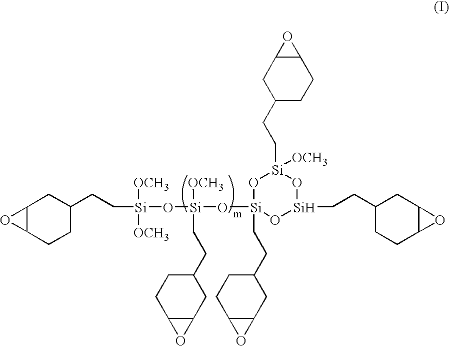
wherein m is an integer ranging from 5 to 50; 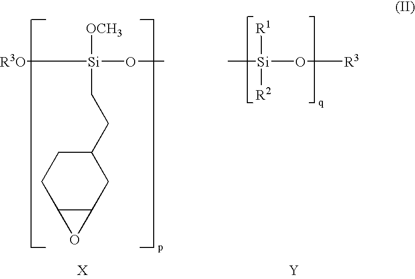
wherein X and Y arc monomer units randomly distributed or occurring together, R¹ and R² are each independently selected from the group of methyl, methoxy, ethyl, ethoxy, propyl, butyl, pentyl, octyl, and phenyl; R³ is methyl or ethyl; p is an integer ranging from 2 to 50; and q is 0 or an integer ranging from to 50.

8. The method of claim 7, wherein R³ is methyl in structure (II).

9. The method of claim 8, wherein, R¹ and R² are both methyl groups in structure (II), and the ratio of p to q ranges from about 8:1 to about 1:1.

10. The method of claim 1, wherein said polymeric material is a formulation comprising a cycloaliphatic epoxy siloxane monomer having structure (III) 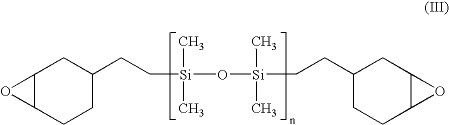
wherein n is an integer ranging from 1 to 3, in combination with a non-silicon-containing epoxy selected from the group of diglycidyl ethers of bisphenol A epoxy resins, epoxidized vegetable oils, epoxidized vegetable oil esters, and 3,4-epoxycyclohexyl 3′,4′-epoxycyclohexane carboxylate; and a diaryliodonium salt polymerization initiator, and optionally, an epoxy siloxane having structure (I) 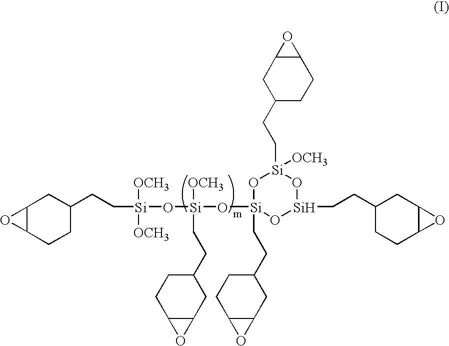
wherein m is an integer from 5 to 50.

11. The method of claim 7, wherein said polymeric material further comprises ingredients selected from the group of flexibilizers, fillers, pigments, diluents, tougheners, flow control agents, antifoaming agents, adhesion promoters, and combinations thereof.

12. The method of claim 1, wherein said silicon-containing material is selected from the group of silicon, silicon oxide, silicon dioxide, silicon oxide/silicon, silicon nitride, silica on silicon, boron-doped silicon, phosphorous-doped silicon, arsenic-doped silicon, and polysilicon.

13. The method of claim 1, further comprising the step of employing water to rinse said aqueous solution of sulfuric acid or phosphoric acid from said at least a portion of the surface of said material.

14. A method of fabricating a useful structure comprising:
a) depositing a first prepolymer layer onto a substrate surface, wherein said first prepolymer is in liquid form;
b) curing said first prepolymer layer to form a first cured polymeric material layer having an exposed surface opposite said substrate surface, wherein said first cured polymeric material layer is in solid form;
c) contacting said exposed surface of said first cured polymer layer with an aqueous solution of sulfuric acid or phosphoric acid, followed by rinsing said aqueous solution of sulfuric acid or phosphoric acid from said exposed surface with water to form a treated surface of said first cured polymer layer;
d) depositing a second prepolymer layer in liquid form onto said treated surface of said first cured polymeric material layer; and
e) curing said second prepolymer layer to form a second cured polymeric material layer in solid form.

15. The method of claim 14, wherein said useful structure is a semiconductor structure, and wherein said substrate is a silicon substrate selected from the group of silicon, silicon oxide, silicon dioxide, silicon oxide/silicon, silicon nitride, silica on silicon, boron-doped silicon, phosphorous-doped silicon, arsenic-doped silicon, and polysilicon.

16. The method of claim 15, further comprising prior to step (a), the step of contacting said silicon substrate surface with an aqueous solution of sulfuric acid or phosphoric acid, followed by rinsing said aqueous solution of sulfuric acid or phosphoric acid from said substrate surface with water.

17. The method of claim 15, wherein said first prepolymer and said second prepolymer are each independently selected from the group of siloxane epoxy polymers, polyimides, parylene (poly-p-xylylene), polynaphthalene, benzocyclobutane (BCB), silicon-containing organic polymers, and aromatic hydrocarbon polymers.

18. The method of claim 17, wherein said first prepolymer and said second prepolymer are each independently cured thermally at a temperature ranging from about 155° C. to about 360° C. or cured by U.V. radiation in steps (b) and (e).

19. The method of claim 15 further comprising after step (b), the step of thermally annealing said first cured polymeric material layer at a temperature ranging from about 200° C. to about 300° C.

20. The method of claim 14, wherein said useful structure is an optical waveguide structure, and wherein said substrate is selected from the group of silicon-containing materials, glass, plastics, quartz, ceramics, or crystalline materials.

21. The method of claim 20, wherein said substrate is a silicon-containing material, and wherein prior to step (a), said method further comprises contacting said silicon-containing material substrate with an aqueous solution of sulfuric acid or phosphoric acid, followed by the step of rinsing said aqueous solution of sulfuric acid or phosphoric acid from said substrate with water.

22. The method of claim 20, wherein said first prepolymer and said second prepolymer are each siloxane epoxy polymers, and wherein said first cured polymeric material layer has a refractive index lower than that of said second cured polymeric material layer.

23. The method of claim 22, wherein said first prepolymer and said second prepolymer are each independently cured thermally at a temperature ranging from about 155° C. to about 360° C. or cured by U.V. radiation in steps (b) and (e).

24. The method of claim 20 further comprising after step (b), the step of thermally annealing said first cured polymeric material layer at a temperature ranging from about 200° C. to about 300° C.

25. The method of claim 14, wherein said useful structure is a coated article, and wherein said substrate is selected from the group of glass, plastic, and metal.

26. The method of claim 25, wherein said first prepolyrner and said second prepolymer are each independently a formulation comprising a cycloaliphatic epoxy siloxane monomer having structure (III) 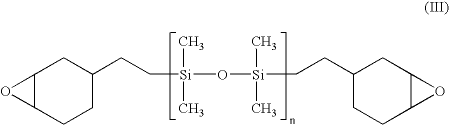
wherein n is an integer ranging from 1 to 3, in combination with a non-silicon-containing epoxy selected from the group of diglycidyl ethers of bisphenol A epoxy resins, epoxidized vegetable oils, epoxidized vegetable oil esters, and 3,4-epoxycyclohexyl 3′,4′-epoxycyclohexane carboxylate; and a diaryliodoniurn salt polymerization initiator, and optionally, an epoxy siloxane having structure (I) 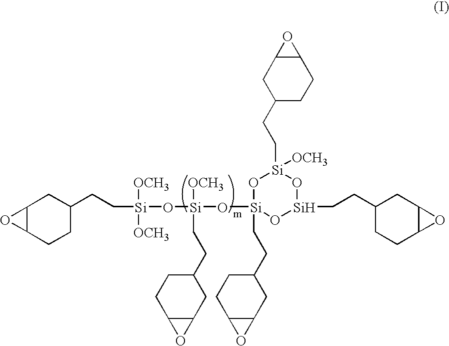
wherein m is an integer from 5 to 50.

27. The method of claim 26, wherein said first prepolymer and said second prepolymer each independently further comprises ingredients selected from the group of flexibilizers, fillers, pigments, diluents, tougheners, flow control agents, antifoaming agents, adhesion promoters, and combinations thereof.

28. The method of claim 25, wherein said first prepolymer and said second prepolymer are each independently cured thermally at a temperature ranging from about 150° C. to about 260° C. or cured by exposure to electron beam radiation ranging from about 3 to about 12 Mrad in steps (b) and (e).

29. A method of fabricating a semiconductor structure comprising:
a) depositing a capping layer onto a metallization layer comprising a first polymeric dielectric layer having a via formed therein, said via being filled with a conductive metal, and wherein said capping layer has an exposed surface opposite said first polymeric dielectric layer and said conductive metal;
b) contacting said exposed surface of said capping layer with an aqueous solution of sulfuric acid or phosphoric acid, followed by rinsing said aqueous solution of sulfuric acid or phosphoric acid from said exposed surface with water to form a treated surface of said capping layer;

28
d) depositing a prepolymer dielectric layer in liquid form onto said treated surface of said capping layer; and
e) curing said second prepolymer dielectric layer to form a second polymeric dielectric layer.

30. The method of claim 28, wherein said capping layer is selected from the group consisting of silicon-containing materials and siloxane epoxy polymers having structures (I) or (II): 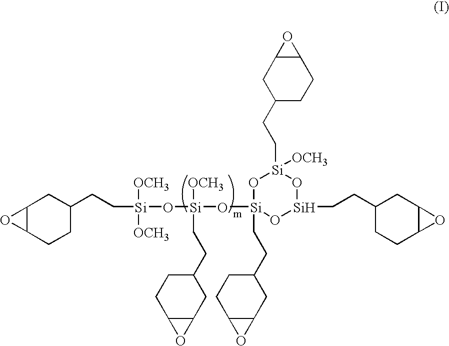
wherein m is an integer ranging from 5 to 50. 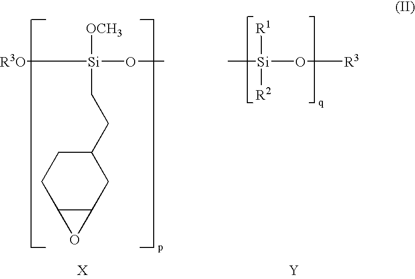
wherein X and Y are monomer units randomly distributed or occurring together, R¹ and R² are each independently selected from the group of methyl, methoxy, ethyl, ethoxy, propyl, butyl, pentyl, octyl, and phenyl; R³ is methyl or ethyl; p is an integer ranging from 2 to 50; and q is 0 or an integer ranging from 1 to 50.

31. The method of claim 29, wherein said capping layer is a silicon-containing material selected from the group consisting of SiN, SiC, SICH, SiCN.

32. The method of claim 29 wherein said first polymeric dielectric layer, said prepolymer dielectric layer, and said second polymeric dielectric layer are each independently selected from the group consisting of siloxane epoxy polymers, polyimides, parylene (poly-p-xylylene), polynaphthalene, benzocyclobutane (BCB), silicon-containing organic polymers, and aromatic hydrocarbon polymers.

32. The method of claim 29, wherein said conductive metal is selected from the group consisting of copper, copper alloys, aluminum, and tungsten.
